(19) United States
(12) Patent Application Publication
(10) Pub. No.: US 2008/0284471 A1
(43) Pub. Date: Nov. 20, 2008

(54) Current load driving circuit

(75) Inventor: Shinichiro Kobayashi, Hino-shi (JP)

Correspondence Address: OLIFF & BERRIDGE, PLC, P.O. BOX 320850, ALEXANDRIA, VA, 22320-4850, US

(73) Assignee: SEIKO EPSON CORPORATION, Tokyo (JP)

(21) Appl. No.: 12/153,046

(22) Filed: May 13, 2008

(30) Foreign Application Priority Data
May 14, 2007 (JP) 2007-127850

(51) Int. Cl. H03K 3/01

(52) U.S. Cl. 327/109

(57) ABSTRACT

A current load driving circuit for driving a current load, including: a first current mirror circuit that outputs a current; and a second current mirror circuit that receives the current outputted from the first current mirror circuit as an input current and then amplifies the input current to drive the current load. The whole of the first current mirror circuit and the second current mirror circuit is divided into an input circuit and an output circuit; and the divided position is provided on a voltage route of the first current mirror circuit or a voltage route of the second current mirror circuit.

The entire disclosure of Japanese Patent Application No. 2007-127850, filed May 14, 2007, is expressly incorporated by reference herein.

### BACKGROUND OF THE INVENTION

1. Field of the Invention

The present invention relates to a current load driving circuit for driving a current load typified by a light emitting diode (hereinafter referred to as “LED”).

2. Description of the Relate Art

An LED driving circuit described in JP-A-2005-116616, for example has been known.

The LED driving circuit properly controls a current flowing into an LED without using a booster circuit. More specifically, the LED driving circuit includes a variable current source, a first current mirror circuit, and a second current mirror circuit.

The variable current source generates a predetermined current using an external impedance circuit. The first current mirror circuit amplifies the current generated by the variable current source. The second current mirror circuit further amplifies the current supplied from the first current mirror circuit and then supplies the amplified current to the LED. Multiple LEDs are lit by the current supplied from the second current mirror circuit.

With an existing LED driving circuit having the above configuration, any current may be generated by the variable current source. Hence, not only a desired driving current is caused to flow into the LED, but a driving current flowing to the multiple LEDs can be readily changed.

In the above existing circuit, when multiple components are arranged on a semiconductor substrate to integrate them into a circuit, it is preferable to locate the components close together in order to ensure operation characteristics.

On the other hand, when such multiple components are formed of transistors on a gate array, for example, the degree of freedom in the layout of the components is increased if the transistors located in remote positions can be used. However, the interconnections become longer, thereby causing the possibility of impairing the operation characteristic.

Under these circumstances, when the components are formed of a gate array or the like, there is a need for an LED driving circuit which has a large degree of freedom in the layout of each component, while the impairment in the operational characteristics is suppressed as much as possible.

In addition, the existing circuits have a drawback in that a current flowing into each of the multiple LEDs cannot be controlled. Such a drawback needs to be solved.

### SUMMARY OF THE INVENTION

An advantage of some aspects of the invention is to provide a current load driving circuit that has a large degree of freedom in the layout of components while the impairment in the operational characteristic is suppressed as much as possible when the components are formed of a gate array or the like.

Another advantage of some aspects of the invention is to provide a current load driving circuit capable of separately controlling the current flowing into each of multiple current loads.

According to a first aspect of the invention, a current load driving circuit for driving a current load, comprising: a first current mirror circuit that outputs a current; and a second current mirror circuit that receives the current outputted from the first current mirror circuit as an input current and then amplifies the input current to drive the current load. The whole of the first current mirror circuit and the second current mirror circuit is divided into an input circuit and an output circuit; and the divided position is provided on a voltage route of the first current mirror circuit or a voltage route of the second current mirror circuit.

According to a second aspect of the invention, a current load driving circuit for driving a current load, comprising: a first current mirror circuit that outputs a current; and a second current mirror circuit that receives the current outputted from the first current mirror circuit as an input current and then amplifies the input current to drive the current load. The whole of the first current mirror circuit and the second current mirror circuit is divided into an input circuit and an output circuit, when the first current mirror circuit and the second current mirror circuit are formed on a semiconductor substrate; and the divided position is provided on a voltage route of the first current mirror circuit.

In the above configuration, it is preferable that the first current mirror circuit include a current source resistor functioning as a current source for supplying a predetermined current to an input side of the first current mirror circuit.

The first current mirror circuit may include an electrostatic protection resistor for protecting a transistor in the first current mirror circuit.

The current source resistor may function not only as the current source but also to protect a transistor in the first current mirror circuit from static electricity.

The first current mirror circuit may include a control circuit for controlling a current of the current load.

The second current mirror circuit may include a control circuit for controlling a current of the current load.

According to a third aspect of the invention, a current load driving circuit for driving a plurality of current loads, comprising: a first current mirror circuit that generates a plurality of output currents based on an input current; and a plurality of second current mirror circuits that receive the plurality of output currents outputted from the first current mirror circuit as input currents, and then amplify the input currents to drive the plurality of current loads. The whole of the first current mirror circuit and the plurality of second current mirror circuits is divided into a single input circuit and a plurality of output circuits; and the divided position is provided on a voltage route of the first current mirror circuit.

According to a fourth aspect of the invention, a current load driving circuit for driving a plurality of current loads, comprising: a first current mirror circuit that generates a plurality of output currents based on an input current; and a plurality of second current mirror circuits that receive the plurality of output currents outputted from the first current mirror circuit as input currents and then amplify the input currents to drive the plurality of current loads. The whole of the current mirror circuits is divided into a single input circuit and a plurality of output circuits, when the first current mirror circuit and the plurality of second current mirror circuits are formed on a semiconductor substrate; and the divided position is provided on a voltage route of the first current mirror circuit.

In the above configuration, it is preferable that the first current mirror circuit include a current source resistor functioning as a current source for supplying a predetermined current to the input side of the first current mirror circuit.

The first current mirror circuit may include an electrostatic protection resistor for protecting a transistor in the first current mirror circuit from static electricity.

The current source resistor may function not only as the current source but also to protect a transistor in the first current mirror circuit from static electricity.

The first current mirror circuit may include a control circuit for collectively controlling currents of the plurality of current loads.

Each of the plurality of second current mirror circuits may include a control circuit for controlling a current of the current load.

According to an aspect of the invention, the currents flowing across multiple current loads are allowed to be controlled collectively, and in addition, are allowed to be controlled separately.

### BRIEF DESCRIPTION OF THE DRAWINGS

FIG. 1 is a circuit diagram illustrating the configuration according to a first embodiment of the invention;

FIG. 2 is a circuit diagram illustrating the configuration according to a second embodiment of the invention;

FIG. 3 is a circuit diagram illustrating a detailed example of the input circuit in FIG. 2;

FIG. 4 is a circuit diagram illustrating another detailed example of the input circuit in FIG. 2;

FIG. 5 is a circuit diagram illustrating another detailed example of the output circuit in FIG. 2;

FIG. 6 is a circuit diagram illustrating the configuration according to a third embodiment of the invention;

FIG. 7 is a circuit diagram illustrating the configuration according to a fourth embodiment of the invention;

FIG. 8 is a circuit diagram illustrating the configuration according to a fifth embodiment of the invention;

FIG. 9 is a circuit diagram illustrating the configuration according to a sixth embodiment of the invention;

FIG. 10 is a circuit diagram illustrating the configuration according to a seventh embodiment of the invention;

FIG. 11 is a circuit diagram illustrating the configuration according to an eighth embodiment of the invention;

FIG. 12 is a circuit diagram illustrating the configuration according to a ninth embodiment of the invention;

FIG. 13 is a circuit diagram illustrating the configuration according to a tenth embodiment of the invention;

FIG. 14 is a circuit diagram illustrating the configuration according to an eleventh embodiment of the invention; and

FIG. 15 is a circuit diagram illustrating the configuration of a variation of the first embodiment of the invention.

### DETAILED DESCRIPTION OF THE PREFERRED EMBODIMENTS

Embodiments of the invention will be described below with reference to the accompanying drawings.

### First Embodiment

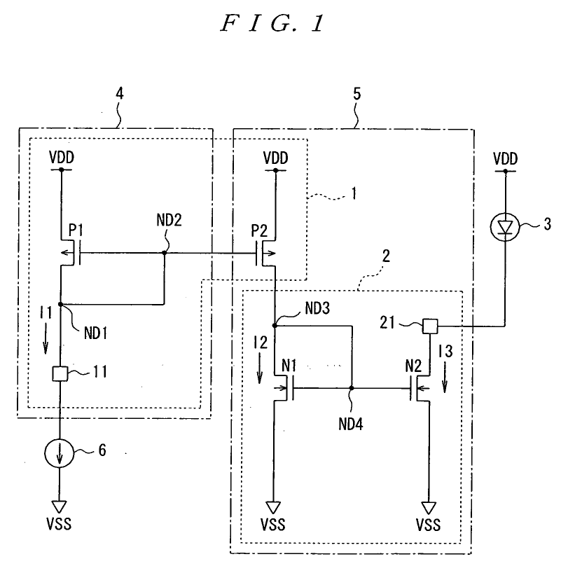

Referring to FIG. 1, a current load driving circuit according to a first embodiment of the invention includes: a first current mirror circuit 1 composed of p-type MOS transistors P1 and P2 the source electrodes of which are connected to a first power supply voltage VDD and the gate electrodes of which are connected to the drain electrode of the MOS transistor P1; and a second current mirror circuit 2 composed of n-type MOS transistors N1 and N2 the source electrodes of which are connected to a second power supply voltage VSS and the gate electrodes of which are connected to the drain electrode of the MOS transistor N1. Hence, the current load driving circuit drives a current load typified by an LED 3.

Prior to a detailed description of the first embodiment, the basic concept of the configuration of the invention will be described, with reference to the first embodiment.

As illustrated in FIG. 1, in the first embodiment, there are included: a first current route into which a current I1 flows such that a current source 6 is connected in series to the drain electrode of the MOS transistor P1 at a node ND1 connected to the gate electrodes of the MOS transistors P1 and P2 through a node ND2; a second current route into which a current I2 flows such that the drain electrodes of the MOS transistors P2 and N1 are connected in series at a node ND3 connected to the gate electrodes of the MOS transistors N1 and N2 through a node ND4; and a third current route into which a current I3 flows such that the MOS transistor N2 is connected in series to an LED 3 at an output terminal (node) 21.

In addition, in the first embodiment, there are included: a first voltage route which is a route electrically connecting the gate electrode of the MOS transistor P1 and the gate electrode of the MOS transistor P2 and in which only a voltage generated by the current I1 flowing into the above first current route is meaningful; and a second voltage route which is a route electrically connecting the gate electrode of the MOS transistor N1 and the gate electrode of the MOS transistor N2 and in which only a voltage generated by the current I2 flowing into the above second current route is meaningful.

When the circuit including such a current route and a voltage route is formed on a semiconductor substrate, the current route and the voltage route respectively include interconnections in addition to MOS transistors (active elements).

In this case, in the current route, the increased length of the interconnection may impair the operation characteristics due to the interconnection resistance or parasitic capacitance of the interconnection. On the other hand, in the voltage route, the terminal of the route voltage is regarded as being terminated with an extremely high resistance. This can eliminate the influence of resistance parasitic the voltage route. Therefore, there is almost no possibility of impairment of the operation characteristics, even if the length of the interconnection is increased.

According to the invention, when components are formed on the semiconductor substrate, the entire circuit is divided or separated to increase the degree of freedom in the layout of the components, while the impairment of the operation characteristics is suppressed as much as possible. A boundary is provided on the voltage route to divide or separate the circuit.

In the first embodiment, based on such a basic concept, the entire circuit is divided or separated into an input circuit 4 and an output circuit 5. The divided position or separated position is provided on the first voltage route, which is the voltage route of the first current mirror circuit 1.

More specifically, in the first embodiment, the components are formed on the semiconductor substrate with a gate array or the like. The input circuit 4 is separated from the output circuit 5, and the separated position of the input circuit 4 and the output circuit 5 is electrically connected by an interconnection.

The detailed configuration of each portion in the first embodiment will now be described.

The first current mirror circuit 1 includes: an input terminal 11; and the MOS transistors P1 and P2. The current source (constant current source) 6 connected to the input terminal 11 supplies a predetermined input current. Thus, the first current mirror circuit 1 amplifies the current I1 of the current source 6 to a current proportional to a multiplier determined by the amplification factors of the MOS transistors P1 and P2, and then outputs the amplified current as the current I2.

The first power supply voltage VDD is applied to the source electrode of the MOS transistor P1. The gate electrode and the drain electrode of the MOS transistor P1 are connected together, and the common connection is connected to the input terminal 11. The first power supply voltage VDD is applied to the source electrode of the MOS transistor P2, the gate electrode thereof is connected to the gate of the MOS transistor P1, and the drain electrode thereof is connected to the drain electrode of the MOS transistor N1.

The second current mirror circuit 2 includes: an output terminal 21; and the MOS transistors N1 and N2. The LED 3 is connected to the output terminal 21. Thus, the second current mirror circuit 2 amplifies the current I2 output from the first current mirror circuit 1 to a current proportional to a multiplier determined by the amplification factors of the MOS transistors N1 and N2, and then outputs the amplified current as the current I3. The LED 3 is lit by the current I3.

The second power supply voltage VSS is applied to the source electrode of the MOS transistor N1. The gate electrode and the drain electrode of the MOS transistor N1 are connected together and the common connection is connected to the drain electrode of the MOS transistor P2 and to the gate electrode of the MOS transistor N2. The second power supply voltage VSS is applied to the source electrode of the MOS transistor N2. The drain electrode of the MOS transistor N2 is connected to the output terminal 21.

An example of the operation according to the first embodiment with the above configuration will now be described with reference to FIG. 1.

In the first current mirror circuit 1, if the current value of the current source 6 is taken as I1, the amount of current same as that of the current flowing from the current source 6 flows into the node ND1, according to Kirchhoff's law. However, connected through the node ND2 are the gate electrodes of the MOS transistor P1 and P2 and the termination resistance is extremely high. Therefore, the current flowing from the node ND2 to the node ND1 is not generated. As a result, the current I1 determined by the current source 6 flows between the source and the drain electrode of the MOS transistor P1 constituting the first current mirror circuit 1. This allows the route from the application portion of the first power supply voltage VDD to the application portion of the second supply voltage VSS through the MOS transistor P1 and the current source 6 to be regarded as the first current route.

On the other hand, no current will flow into the route from the node ND1 to the gate electrodes of the MOS transistors P1 and P2 through the node ND2. The current I1 flowing between the source and the drain electrode of the MOS transistor P1 generates a voltage drop due to the ON resistance of the MOS transistor P1. This generates a voltage across the node ND1. The voltage generated by the voltage drop is applied to the gate electrode of the MOS transistor P1 through the node ND2. For this reason, the MOS transistor P1 is stabilized at any operation point thereof by the voltage of the gate electrode and the ON resistance. The route from the node ND1 through the node ND2 can be regarded as the first voltage route, because only the voltage of the route influences the operation. The voltage equivalent to the voltage drop of the MOS transistor P1 is applied to the gate electrode of the MOS transistor P2.

In the MOS transistors P1 and P2, if the threshold voltage of the MOS transistor P1 is taken as VTP1, the voltage between the gate electrode and the source electrode of the MOS transistor P1 is taken as VGSP1, and the amplification factor of the MOS transistor P1 is taken as PP1, the current I1 is represented by the following equation.

I1=(βP1/2)×(VGSP1−VTP1)²

In addition, if the threshold voltage of the MOS transistor P2 is taken as VTP2, the voltage between the gate electrode and the source electrode of the MOS transistor P2 is taken as VGSP2, and the amplification factor of the MOS transistor P2 is taken as PP2, the current I2 is represented by the following equation.

I2=(βP2/2)×(VGSP2−VTP2)²

If the MOS transistors P1 and P2 are the same in the characteristic, the VTP1 is equal to the VTP2. Accordingly, the VGSP1 is also equal to the VGSP2 because the drain and the gate electrode of MOS transistor P1 and the gate electrode of the MOS transistors P2 are the same in the electric potential. A current amplification factor I2/I1 is represented by the following equation.

I2/I1=βP2/βP1

The current I2 in the first current mirror circuit 1 is determined by the current I1 and the ratio β between the MOS transistor P1 and the MOS transistor P2.

In the second current mirror circuit 2, the amount of current same as that of the current flowing into the node ND3 from the MOS transistor P2 flows out of the node ND3, according to Kirchhoff's law. However, connected through the node ND4 is only the gate electrodes of the MOS transistor N1 and N2, and the termination resistance is extremely high. Therefore, no current is generated from the node ND3 to the node ND4. As a result, the current I2 determined by the MOS transistor P2 flows between the source and the drain electrode of the MOS transistor N1. This allows the route from the application portion of the first power supply voltage VDD to the application portion of the second supply voltage VSS through the MOS transistors P2 and N1 to be regarded as the second current route.

On the other hand, no current will flow into the route from the node ND3 to the gate electrodes of the MOS transistors N1 and N2 through the node ND4. The current I2 flowing between the source electrode and the drain electrode of the MOS transistor N1 generates a voltage drop due to the ON resistance of the MOS transistor N1. This generates a voltage across the node N3. The voltage generated by the voltage drop is applied to the gate electrode of the MOS transistor N1 through the node ND4. For this reason, the MOS transistor N1 is stabilized at any operation point thereof by the voltage of the gate electrode and the ON resistance. Therefore, the route from the node ND3 through the node ND4 is allowed to be regarded as the second voltage route, because only the voltage of the route influences the operation. The voltage equivalent to the voltage drop of the MOS transistor N1 is applied to the gate electrode of the MOS transistor N2.

In the MOS transistors N1 and N2, if the threshold voltage of the MOS transistor N1 is taken as VTN1, the voltage between the gate electrode and the source electrode of the MOS transistor N1 is taken as VGSN1, and the amplification factor of the MOS transistor N1 is taken as βN1, the current I2 is represented by the following equation.

I2=(βN1/2)×(VGSN1−VTN1)²

If the threshold voltage of the MOS transistor N2 is taken as VTN2, the voltage between the gate electrode and the source electrode of the MOS transistor N2 is taken as VGSN2, and the amplification factor of the MOS transistor N2 is taken as βN2, the current I3 is represented by the following equation.

I3=(βN2/2)×(VGSN2−VTN2)

If the MOS transistors N1 and N2 are the same in the characteristic, the VTN1 is equal to the VTN2. The VGSN1 is also equal to the VGSN2 because the drain and the gate electrode of MOS transistor P1 and the gate electrode of the MOS transistors N2 are same in the electric potential. Accordingly, a current amplification factor I3/I2 is represented by the following equation.

I3/I2=βN2/βN1

The current I3 in the second current mirror circuit 2 is determined by the current I2 and the ratio β between the MOS transistor N1 and the MOS transistor N2. The LED 3 is lit by the current I3.

For example, assuming that the current I1 of the current source 6 is 1 mA, the amplification factor of the MOS transistors P1 and that of P2 are the same, and the amplification factor of the MOS transistors N2 is ten times as high as that of the MOS transistors N1. Under such conditions, the current I3 flowing into the MOS transistor N2 is 10 mA, and this allows the LED3 to be lit.

Accordingly, in the first embodiment, the current value I1 of the current source 6 is amplified by the first current mirror circuit 1 and the second current mirror circuit 2 to obtain the current I3, so that a desired current can be flown into the LED 3 to allow the LED 3 to be lit.

As described heretofore, in the first embodiment, the entire circuit is divided into the input circuit 4 and the output circuit 5. The divided position is provided on the first voltage route, which is the voltage route of the first current mirror circuit 1. Such a division on the voltage route eliminates the influence of resistance component parasite on the interconnection for connecting the input circuit 4 and the output circuit 5. For this reason, even when the input circuit 4 and the output circuit 5 are arranged at any position and electrically interconnected together in the configuration with a gate electrode array or the like, no influence is exerted by the resistance component parasite on the interconnection. This suppresses impairment of the operation characteristic, thereby allowing a desired operation characteristic to be maintained. Consequently, according to the first embodiment, the degree of freedom in the layout of each component can be increased while impairment of the operation characteristic is suppressed in the case where each component is arranged on a semiconductor substrate.

In the first embodiment, the entire circuit is divided into the input circuit 4 and the output circuit 5. The divided position is provided on the first voltage route, which is the voltage route of the first current mirror circuit 1. However, the divided position may be provided on the second voltage route, which is the voltage route of the second current mirror circuit 2. In particular, since the MOS transistor N2 is directly connected to the outside of a semiconductor apparatus and a current greater than that flown into the MOS transistors P1, P2, or N1 is flown into the MOS transistor N2, the MOS transistor N2 is generally arranged in a dedicated region. For this reason, regions where the MOS transistors N1 and N2 are arranged are apart from each other. However, this allows the influence exerted on the operation characteristic to be eliminated.

Also, the divided position may be provided on both voltage routes of the current mirror circuits 1 and 2. In this case, the entire circuit according to the first embodiment is divided into three portions. These points apply to the following embodiments.

### Second Embodiment

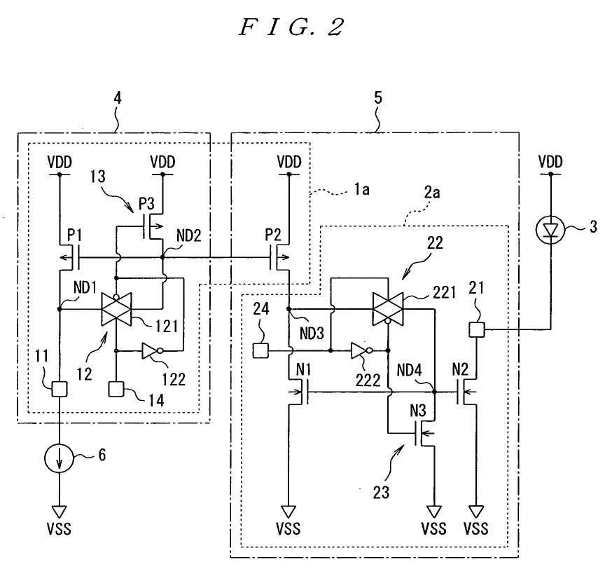

Referring now to FIG. 2, a current load driving circuit according to a second embodiment of the invention includes: a first current mirror circuit 1a; and a second current mirror circuit 2a, so as to drive a current load such as an LED 3 and to control turning on and off of the current flowing into the LED 3.

That is to say, the second embodiment is devised based on the configuration of the first embodiment illustrated in FIG. 1. The first current mirror circuit 1a further includes: a switching circuit 12; a clamping circuit 13; and a control terminal 14, in addition to the configuration of the current mirror circuit 1 of FIG. 1. The second current mirror circuit 2a further includes: a switching circuit 22; a clamping circuit 23; and a control terminal 24, in addition to the configuration of the current mirror circuit 2 of FIG. 1.

In the second embodiment, in the same manner as the first embodiment, the entire circuit is divided or separated into the input circuit 4 and the output circuit 5, and the divided position or the separated position is provided on the voltage route of the first current mirror circuit 1a.

In addition, since the configuration according to the second embodiment is same as that of the first embodiment except for the above circuits that are added, the same reference numerals will be given to the same components to omit the descriptions thereof.

The switching circuit 12 is composes of: a transmission gate 121; and an inverter 122, so as to turn on and off the connection between the gate electrode and the drain electrode of the MOS transistor P1, according to a control signal inputted to the control terminal 14. The clamping circuit 13 is composed of a MOS transistor P3. The MOS transistor P3 secures the gate electrodes of the MOS transistors P1 and P2 to the first power supply, according to an inverted signal, which has been inverted by the inverter 122, of a control signal inputted to the control terminal 14. Also, in a conduction state of the transmission gate 121, an ON resistance lies in a MOS transistor constituting the transmission gate 121. However, the ON resistance does not influence the operation characteristic because the route from the node ND1 to the gate electrodes of the MOS transistors P1 and P2 through the node ND2 is the voltage route.

The switching circuit 22 is composed of: a transmission gate 221; and an inverter 222, so as to turn on and off the connection between the gate electrode and the drain electrode of the MOS transistor N1 according to a control signal inputted to the control terminal 24. The clamping circuit 23 is composed of a MOS transistor N3. The MOS transistor N3 secures the gate electrodes of the MOS transistors N1 and N2 to the second power supply according to an inverted signal, which has been inverted by the inverter 222, of a control signal inputted into the control terminal 24. Also, in the conduction state of the transmission gate 221, the ON resistance lies in a MOS transistor constituting the transmission gate 221. However, the ON resistance does not influence the operation characteristic because the route from the node ND3 to the gate electrodes of the MOS transistors N1 and N2 through the node ND4 is the voltage route.

According to the second embodiment with such a configuration, the switching circuit 12 is allowed to turn on and off the connection between the gate electrode and the drain electrode of the MOS transistor P1. The clamping circuit 13 secures the gate electrodes of the MOS transistors P1 and P2 to the first power supply VDD when the connection is turned off. At this point, even if the MOS transistors N1 and N2 of the second current mirror circuit 2a are in an operation state, the electric potential at the node ND3 is shifted by the MOS transistor N1 to the second power supply voltage VSS and turns into a cutoff voltage of the MOS transistor N1. For this reason, the MOS transistor N1 is stabilized in its cut-off state, so that the electric potential at the node ND3 is also stabilized. Since the electric potential at the node ND3 is applied to the gate electrode of the MOS transistor N2 through the node ND4, the MOS transistor N2 is also in a cut-off state. This allows the first current mirror circuit 1a to surely control the lighting of the LED 3 and to stop the current flowing thereinto and into the LED 3 when lighting is not required.

In addition, the switching circuit 22 enables the connection between the gate electrode and the drain electrode of the MOS transistor N1 to be turned on and off. The clamping circuit 23 secures the gate electrodes of the MOS transistors N1 and N2 to the second power supply VSS, when the connection is turned off. Therefore, this allows the second current mirror circuit 2a to surely control the lighting of the LED 3.

As stated heretofore, according to the second embodiment, the lighting of the LED 3 can be controlled with ensuring low power consumption. Furthermore, according to the second embodiment, the action and effect of the first embodiment can be achieved.

Specific Configuration According to Second Embodiment

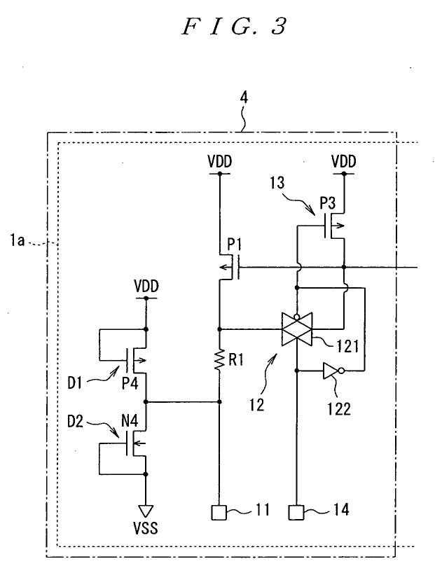

The specific configuration of substantial parts according to the second embodiment will be described with reference to FIGS. 3 to 5.

The following examples are formed of a gate array, for example.

FIG. 3 includes a protective circuit in addition to the configuration of the input circuit 4 illustrated in FIG. 2. The protective circuit includes: electrostatic protection diodes D1 and D2 formed of the MOS transistors P4 and N4, respectively; and an electrostatic protection resistor R1 to protect the MOS transistor P1 from static electricity. Each of the electrostatic protection diodes D1 and D2 is formed of a single MOS transistor in the figure. However, in fact, it is formed of multiple MOS transistors. Alternatively, it may be formed of a diode element or the like.

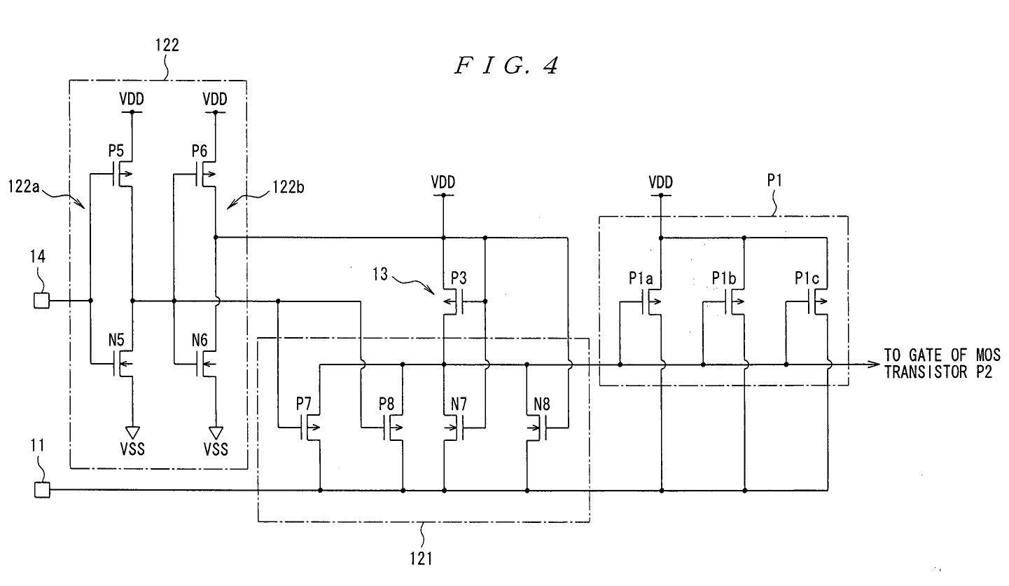

FIG. 4 illustrates a specific example of the configuration of the MOS transistor P1, the transmission gate 121, the inverter 122 and the clamping circuit 13 in the input circuit 4 in FIG. 2.

The MOS transistor P1 is composed of multiple (three in this example) MOS transistors P1a to P1c connected in parallel. The transmission gate 121 is composed of: two p-type MOS transistors P7 and P8 connected in parallel; and two n-type MOS transistors N7 and N8 connected in parallel. The circuit corresponding to the inverter 122 is composed of: a first CMOS inverter 122a composed of a p-type MOS transistor P5 and an n-type MOS transistor N5; and a second CMOS inverter 122b composed of a p-type MOS transistor P6 and an n-type MOS transistor N6.

The output of the first CMOS inverter 122a is supplied to the gate electrode of the second CMOS inverter 122b and the gate electrodes of the MOS transistors P7 and P8 constituting the transmission gate 121, so as to control turning on and off of the MOS transistors. The output of the second CMOS inverter 122b is an inversion of the output of the first CMOS inverter 122a, and is supplied to the gate electrode of the MOS transistor P3 constituting the clamping circuit 13 and the gates electrodes of the MOS transistors N7 and N8 constituting the transmission gate 121, so as to control turning on and off of the MOS transistors.

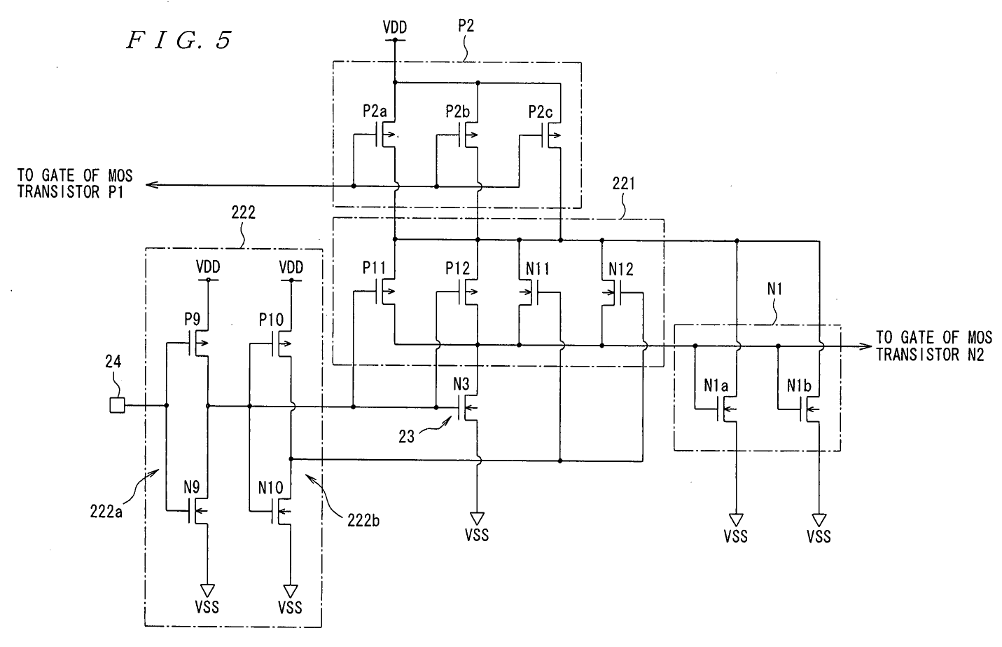

FIG. 5 illustrates a specific example of the configuration of the MOS transistor P2, the MOS transistor N1, the transmission gate 221, the inverter 222, and the clamping circuit 23 in the output circuit 5 in FIG. 2.

The MOS transistor P2 is composed of multiple (three in this example) MOS transistors P2a to P2c connected in parallel. The MOS transistor N1 is composed of two MOS transistors N1a and N1b connected in parallel. The transmission gate 221 is composed of: two p-type MOS transistors P11 and P12 connected in parallel; and two n-type MOS transistors N11 and N12 connected in parallel. The circuit corresponding to the inverter 222 includes: a first CMOS inverter 222a composed of a p-type MOS transistor P9 and an n-type MOS transistor N9; and a second CMOS inverter 222b composed of a p-type MOS transistor P10 and an n-type MOS transistor N10.

The output of the first CMOS inverter 222a is supplied to the gate electrode of the second CMOS inverter 222b, the gate electrode of the MOS transistor N3 constituting the clamping circuit 23, and the gate electrodes of the MOS transistors P11 and P12 constituting the transmission gate 221, so as to control turning on and off of the MOS transistors. The output of the second CMOS inverter 222b is an inversion of the output of the first CMOS inverter 222a, and is supplied to the gate electrodes of the MOS transistors N11 and N12 constituting the transmission gate 221 so as to control turning on and off of the MOS transistors.

### Third Embodiment

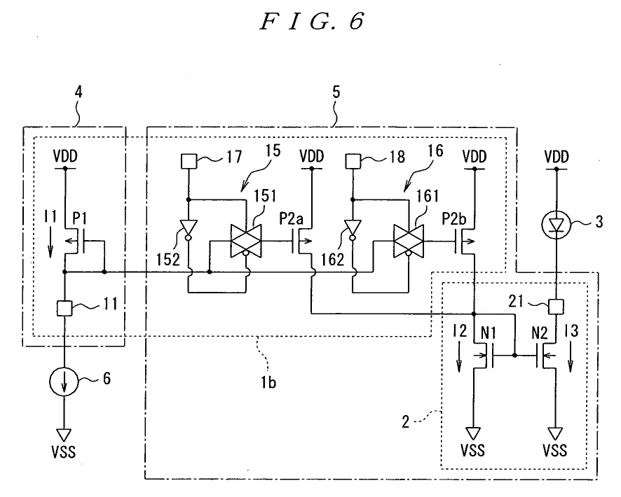

Referring now to FIG. 6, there is provided a current load driving circuit according to a third embodiment of the invention including: a first current mirror circuit 1b; and a second current mirror circuit 2, so as to control a current flowing to a current load such as an LED 3.

That is to say, the third embodiment is devised based on the configuration of the first embodiment illustrated in FIG. 1. The first current mirror circuit 1b is configured such that the MOS transistor P2 in the first current mirror circuit 1 of FIG. 1 is changed to multiple (two in this example) MOS transistors P2a and P2b. Switching circuits 15 and 16 and control terminals 17 and 18 are further included as a control circuit for controlling tuning on and off of the current flowing to the MOS transistors.

In the third embodiment, in the same manner as the first embodiment, the entire circuit is divided into the input circuit 4 and the output circuit 5, and the divided position is provided on the voltage route of the first current mirror circuit 1b.

In addition, the third embodiment has the same configuration as that of the first embodiment except for the additional circuits described above, so that the same reference numerals will be given to the same components to omit the descriptions thereof.

The switching circuit 15 is composed of: a transmission gate 151; and an inverter 152, and is arranged between the gate electrodes of the MOS transistors P1 and P2a. A control signal inputted into the control terminal 17 causes the switching circuit 15 to turn on and off the connection between the gate electrodes of the MOS transistors P1 and P2a.

The switching circuit 16 is composed of: a transmission gate 161; and an inverter 162, and is arranged between the gate electrodes of the MOS transistors P1 and P2b. A control signal inputted into the control terminal 18 causes the switching circuit 16 to turn on and off the connection between the gate electrodes of the MOS transistors P1 and P2b.

An operation example of the third embodiment with such a configuration will now be described.

When both the switching circuits 15 and 16 are turned on, a voltage across the gate electrode of the MOS transistor P1 is applied to the gate electrodes of the MOS transistors P2a and P2b, respectively. For this reason, flown between the source electrodes and drain electrodes of the MOS transistors P2a and P2b are the current I1 and the current I2 that is proportional to the ratio between the amplification factor of the MOS transistor P1 and the sum of the amplification factors of the MOS transistors P2a and P2b. The current I2 is flown into the drain electrode of the MOS transistor N1, and then the current I2 is amplified by the second current mirror circuit 2 to turn into the current I3 of the MOS transistor N2. This lights the LED 3.

When the switching circuit 15 is turned on and the switching circuit 16 is turned off, flown between the source electrode and the drain electrode of the MOS transistor P2a are the current I1 and the current I2 proportional to the ratio between the amplification factor of the MOS transistor P1 and that of the MOS transistor P2a. The current I2 also flows into the drain electrode of the MOS transistor N1. In this case, the current of the MOS transistor N2 in the second current mirror circuit 2 is smaller than that of the above case. This lights the LED 3. The same applies to the case where the switching circuit 15 is turned off and the switching circuit 16 is turned on.

When both the switching circuits 15 and 16 are turned off, the MOS transistors P2a and P2b are turned off, thereby making unstable the voltage across the drain electrode of the MOS transistor N1. However, if the voltage of the gate electrode of the MOS transistor N1 is greater than the threshold voltage (Vth), the MOS transistor N1 is turned on, and then the voltage of the drain electrode thereof drops to the threshold voltage or lower. Thereby, the voltage of the gate electrode of the MOS transistor N2 drops to the threshold voltage or lower, and the voltage is maintained. However, in fact, the voltage is shifted to the second power supply VSS because of a leak current. Consequently, the voltage of the gate electrode of the MOS transistor N1 also drops to the threshold voltage or lower. This turns off the MOS transistor N1, and does not cause a current to flow.

As described heretofore, in the third embodiment, the first current mirror circuit 1b has multiple MOS transistors P2a and P2b, so as to separately control the current flowing into the multiple MOS transistors. Accordingly, the current for lighting the LED 3 can be controlled. For this reason, by establishing a predetermined relationship between characteristics of the MOS transistor M1 and the MOS transistors P2a and P2b, the variation in the current for lighting the LED 3 can be handled, and lighting of one LED 3 or two LEDs 3 can be chosen. Furthermore, according to the third embodiment, the action and effect of the first embodiment can be achieved in the same manner as the first embodiment.

### Fourth Embodiment

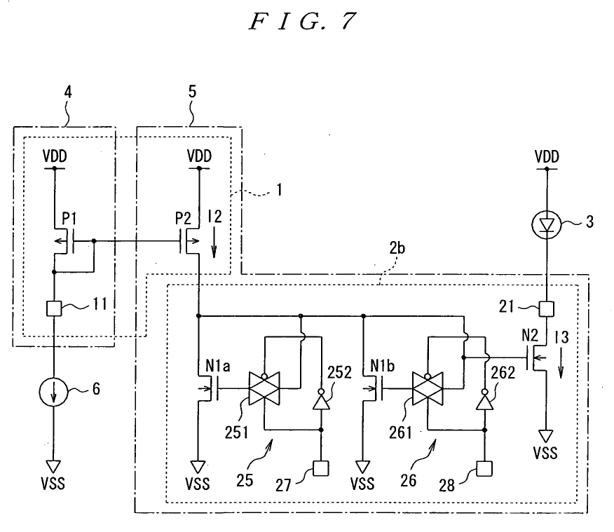

Referring now to FIG. 7, a current load driving circuit according to a fourth embodiment of the invention includes: a first current mirror circuit 1; and a second current mirror circuit 2b, so as to control the current flowing to the current load such as an LED 3.

That is to say, the fourth embodiment is devised based on the configuration of the first embodiment illustrated in FIG. 1. The second current mirror circuit 2b is configured such that the MOS transistor N1 in the first current mirror circuit 2 in FIG. 1 is changed to multiple (two in this example) MOS transistors N1a and N1b. Switching circuits 25 and 26 and control terminals 27 and 28 are further included in the second current mirror circuit 2b as a circuit for controlling tuning on an off of a current flowing into the MOS transistors.

In the fourth embodiment, in the same manner as first embodiment, the entire circuit is divided into the input circuit 4 and the output circuit 5 and the divided position is provided on the voltage route of the first current mirror circuit 1.

The configuration of the fourth embodiment is same as that of the first embodiment except for the further included circuits as described, so that the same reference numerals will be given to the same components to omit the descriptions thereof.

The switching circuit 25 is composed of: a transmission gate 251; and an inverter 252, and is arranged between the gate electrode and the drain electrode of the MOS transistor N1a. A control signal inputted into the control terminal 27 causes the switching circuit 25 to turn on and off the connection between the gate electrode and the drain electrode of the MOS transistors N1a.

The switching circuit 26 is composed of: a transmission gate 261; and an inverter 262, and is arranged between the gate electrode and the drain electrode of the MOS transistor N1b. A control signal inputted into the control terminal 28 causes the switching circuit 26 to turn on and off the connection between the gate electrode and the drain electrode of the MOS transistor N1b.

An operation example of the fourth embodiment with such a configuration will be described below. When both the switching circuits 25 and 26 are turned on, the current flowing into the MOS transistor P2 flows into the MOS transistors N1a and N1b. Thus, flown between the source electrode and the drain electrode of the MOS transistor N2 are the current I2 from the MOS transistor P2 and the current I3 that is proportional to the ratio between the sum of the amplification factors of the MOS transistors N1a and N1b and the amplification factor of the MOS transistor N1. The current I3 lights the LED 3.

When the switching circuit 25 is turned on and the switching circuit 26 is turned off, current flows only to the MOS transistor N1a. Accordingly, the current generates the gate voltage of the MOS transistor N2. Thus, flown between the source electrode and the drain electrode of the MOS transistor N2 are the current I2 from the MOS transistor P2 and the current I3 proportional to the ratio between the amplification factor of the MOS transistor N1a and that of the MOS transistor N2. The current I3 lights the LED 3.

As described above, in the fourth embodiment, the second current mirror circuit 2b has multiple MOS transistors N1a and N1b, so as to separately control the current flowing into the MOS transistors. Therefore, the current for lighting the LED 3 can be controlled. By establishing a predetermined relationship between characteristics of the MOS transistors N1a and N1b, the lighting of the LED 3 can be controlled in a desired manner.

### Fifth Embodiment

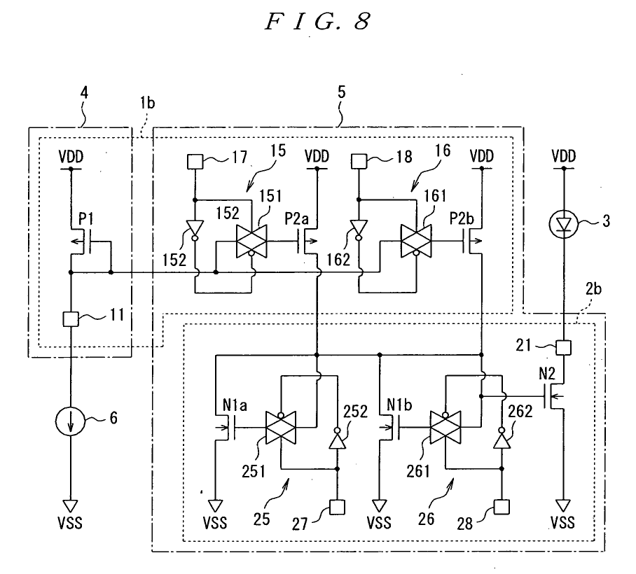

Referring now to FIG. 8, a current load driving circuit according to a fifth embodiment of the invention is a combination of the third embodiment in FIG. 6 and the fourth embodiment in FIG. 7.

Such a configuration allows further fine control of the current flowing into the current load such as the LED 3.

### Sixth Embodiment

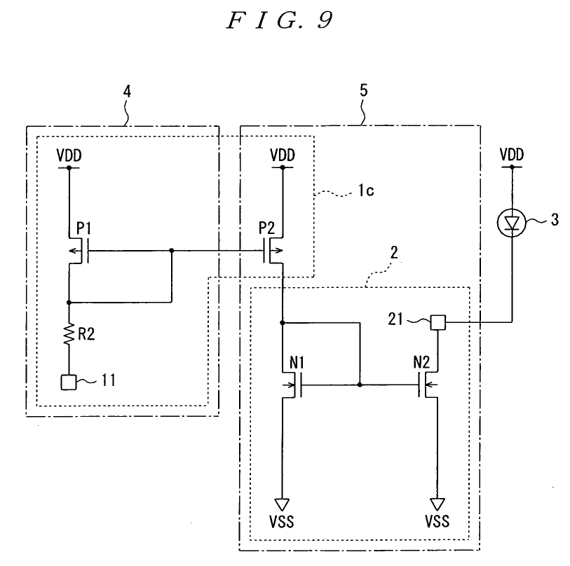

Referring now to FIG. 9, a current load driving circuit according to a sixth embodiment of the invention includes: a first current mirror circuit 1c; and a second current mirror circuit 2b, so as to control the current flowing into a current load such as the LED 3.

That is to say, the sixth embodiment is devised based on the configuration of the first embodiment illustrated in FIG. 1. The first current mirror circuit 1 according to the first embodiment is changed to the first current mirror circuit 1c illustrated in FIG. 9. Specifically, the first current mirror-circuit 1c includes: a current source resistor R2 functioning as a current source to omit the current source 6 in FIG. 1.

In the sixth embodiment, in the same manner as the first embodiment, the entire circuit is divided into the input circuit 4 and the output circuit 5 and the divided position is provided on the voltage route of the first current mirror circuit 1c.

The configuration of the sixth embodiment is same as that of the first embodiment except for the above configuration that is changed, so that the same reference numerals will be given to the same components to omit the descriptions thereof.

According to the sixth embodiment, in the first current mirror circuit 1c, if the first power supply voltage is taken as VDD, the threshold voltage of the MOS transistor P1 is taken as VTP1, the voltage between the gate and the source of the MOS transistor P1 is taken as VGSP1, and the amplification factor of the MOS transistor P1 is taken as βP1, the value of the current source resistor R2 is determined by the following equation.

R2=[VDD−VTP1−√({(2·I1)/βP1}]/I1

Now, by selecting the value of the current source resistor R2 that satisfies the above equation and the amplification factor of the MOS transistor P1, any external current source can be omitted. In addition, by setting the value of the current source resistor R2 to be a sufficient one so as to protect the static electricity, the current source resistor R2 can be also used as a resistor for protecting the static electricity. Furthermore, according to the sixth embodiment, the same action and effect as those of the first embodiment can be achieved.

### Seventh Embodiment

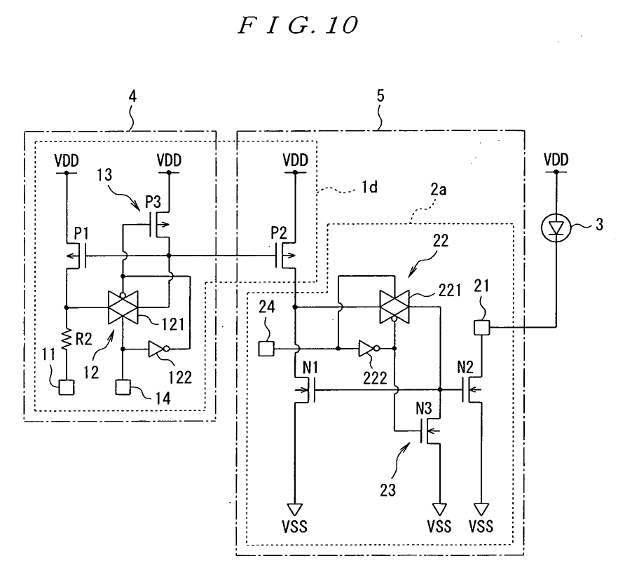

Referring now to FIG. 10, a current load driving circuit according to a seventh embodiment of the invention includes: a first current mirror circuit 1d; and a second current mirror circuit 2a. The seventh embodiment is devised so as to drive a current load such as the LED 3 and to control turning on and off of the current flowing into the LED 3.

That is to say, the seventh embodiment is devised based on the configuration of the second embodiment illustrated in FIG. 2. The configuration of the first current mirror circuit 1 of the second embodiment is changed to that of the first current mirror circuit 1d illustrated in FIG. 10. Specifically, the first current mirror circuit 1d includes a current source resistor R2 functioning as a current source, and the current source 6 in FIG. 2 is omitted.

In the seventh embodiment, in the same manner as the second embodiment, the entire circuit is divided into the input circuit 4 and the output circuit 5, and the divided position is provided on the voltage route of the first current mirror circuit 1d.

The configuration of the seventh embodiment is same as that of the second embodiment except for the configuration that is changed, so that the same reference numerals will be given to the same components to omit the descriptions thereof.

According to the above seventh embodiment, since the first current mirror circuit 1d includes the current-source resistor R2, the current source can be eliminated. Furthermore, according to the seventh embodiment, the same action and effect as those of the second embodiment can be achieved.

The seventh embodiment is devised based on the configuration of the second embodiment illustrated in FIG. 2. However, instead of this, the seventh embodiment may be devised based on the third to fifth embodiment in FIGS. 6 to 8.

### Eighth Embodiment

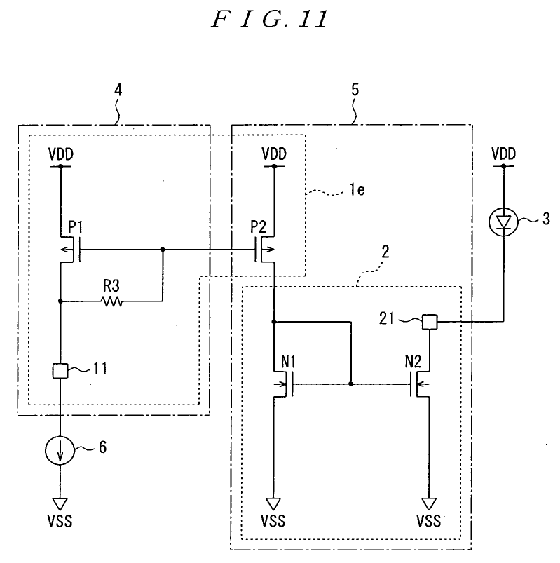

Referring to FIG. 11, a current load driving circuit according to an eighth embodiment of the invention includes: a first current mirror circuit 1e; and a second current mirror circuit 2, so as to drive a current load such as the LED 3.

That is to say, the eighth embodiment is devised based on the configuration of the first embodiment illustrated in FIG. 1. The configuration of the first current mirror circuit 1 is changed to that of the first current mirror circuit 1e illustrated in FIG. 11. Specifically, an electrostatic protection resistor R3 for protecting the gate electrodes of the MOS transistors P1 and P2 from the static electricity is provided between the drain electrode of the MOS transistor P1 provided on the external current source side of the first current mirror circuit 1e and the gate electrodes of the MOS transistors P1 and P2.

The addition of the electrostatic protection resistor R3 will not affect the operation characteristic, even if the value of the electrostatic protection resistor R3 varies due to the variation in the production. In the eighth embodiment, in the same manner as the first embodiment, the entire circuit is divided into the input circuit 4 and the output circuit 5 and the divided position is provided on the voltage route of the first current mirror circuit 1e.

Also, the configuration of the eighth embodiment is same as that of the first embodiment except for the configuration that is changed, so the same reference numerals will be given to the same components to omit the descriptions thereof.

According to the above eighth embodiment, since the first current mirror circuit 1e includes the electrostatic protection resistor R3, the MOS transistors P1 and P2 can be protected from static electricity. Furthermore, according to the eighth embodiment, the same action and effect as those of the first embodiment can be achieved.

### Ninth Embodiment

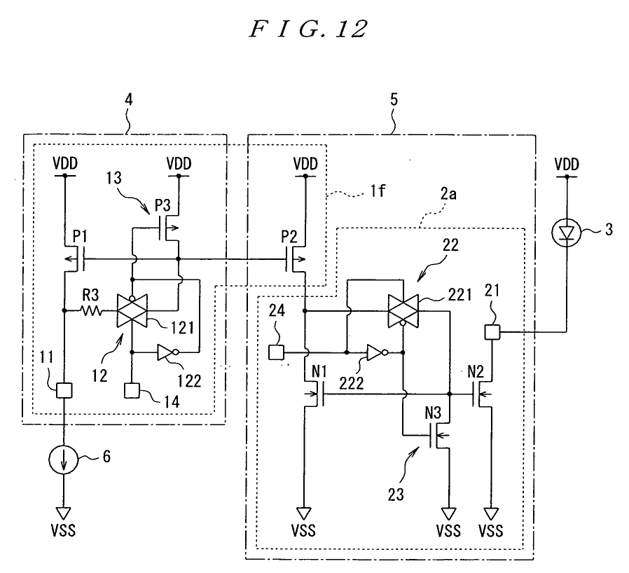

Referring now to FIG. 12, a current load driving circuit according to a ninth embodiment of the invention includes: a first current mirror circuit 1f; and a second current mirror circuit 2a, so as to drive a current load such as the LED 3 and to control turning on and off of the current flowing into the LED 3.

That is to say, the ninth embodiment is devised based on the configuration of the second embodiment illustrated in FIG. 2. The configuration of the first current mirror circuit 1a according to the second embodiment is changed to that of the first current mirror circuit 1f illustrated in FIG. 12. Specifically, the first current mirror circuit 1f is devised based on the first current mirror circuit 1a illustrated in FIG. 2. An electrostatic protection resistor R3 for protecting the gate electrodes of the MOS transistors P1 and P2 from the static electricity is further provided between the drain electrode of the MOS transistor P1 and the gate electrodes of the MOS transistors P1 and P2.

In the ninth embodiment, in the same manner as the second embodiment, the entire circuit is divided into the input circuit 4 and the output circuit 5 and the divided position is provided on the voltage route of the first current mirror circuit 1f.

Also, the configuration of the ninth embodiment is same as that of the second embodiment except for the configuration that is changed, so that the same reference numerals will be given to the same components to omit the descriptions thereof.

According to the ninth embodiment, since the first current mirror circuit 1f includes the electrostatic protection resistor R3, the MOS transistors P1 and P2 can be protected from the static electricity. Furthermore, according to the ninth embodiment, the same action and effect as those of the second embodiment can be achieved.

The ninth embodiment is devised based on the configuration of the second embodiment illustrated in FIG. 2. However, instead of this, the ninth embodiment may be devised based on the third to fifth embodiment in FIGS. 6 to 8.

### Tenth Embodiment

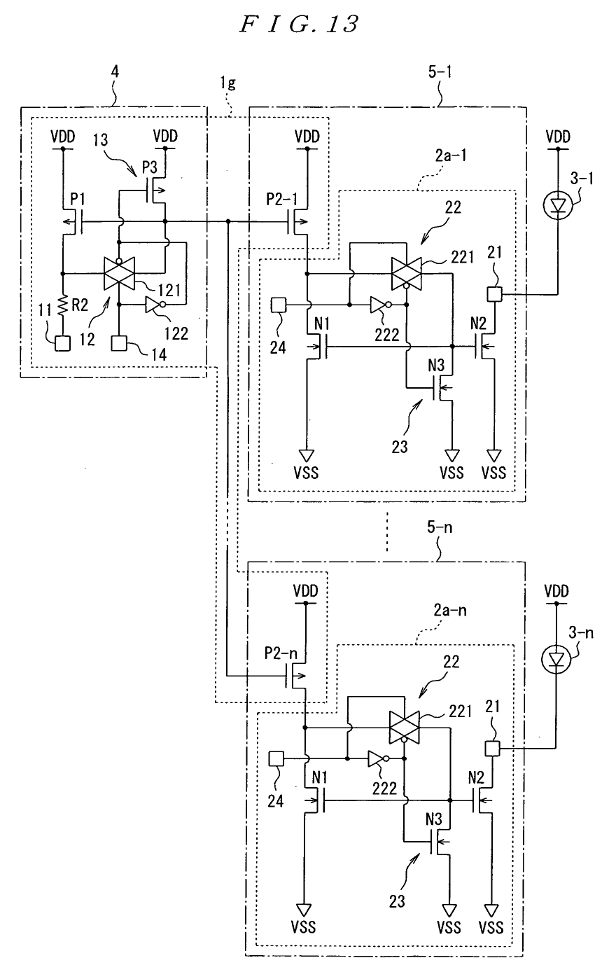

Referring now to FIG. 13, a current load driving circuit according to a tenth embodiment of the invention includes: a first current mirror circuit 1g; and multiple second current mirror circuits 2a-1 to 2a-n. The second current mirror circuits 2a-1 to 2a-n are configured to drive LEDs 3-1 to 3-n, respectively, which are current loads, and to separately or collectively control turning on and off of the current flowing into the LEDs 3-1 to 3-n.

That is to say, in the tenth embodiment, the first current mirror circuit 1d according to the seventh embodiment illustrated in FIG. 10 is changed to the first current mirror circuit 1g, and the second current mirror circuit 2a according to the seventh embodiment is changed to n second current mirror circuits 2a-1 to 2a-n.

Specifically, the first current mirror circuit 1g is devised based on the configuration of the first current mirror circuit 1d illustrated in FIG. 10, and the MOS transistor P2 is changed to multiple MOS transistors P2-1 to P2-n. The n second current mirror circuits 2a-1 to 2a-n are devised based on the configuration the second current mirror circuit 2a illustrated in FIG. 10.

In the tenth embodiment, as illustrated in FIG. 13, the entire circuit is divided into a single input circuit 4 and n output circuits 5-1 to 5-n, and the divided position is provided on the voltage route of the first current mirror circuit 1g.

Also, the tenth embodiment is based on the configuration of the seventh embodiment in FIG. 10 except for the configuration that is changed, so that the same reference numerals will be given to the same components to omit the descriptions thereof.

According to the tenth embodiment, the switching circuit 12 enables collective control of each current flowing into the n LEDs 3-1 to 3-n, thereby enabling the collective control of the lightings thereof. On the other hand, the switching circuits 22 included in the n second current mirror circuits 2a-1 to 2a-n allow separate control of each current flowing into the n LEDs 3-1 to 3-n, thereby allowing the separate control of the lightings thereof. Furthermore, according to the tenth embodiment, the same action and effect as those of the seventh embodiment can be achieved.

### Eleventh Embodiment

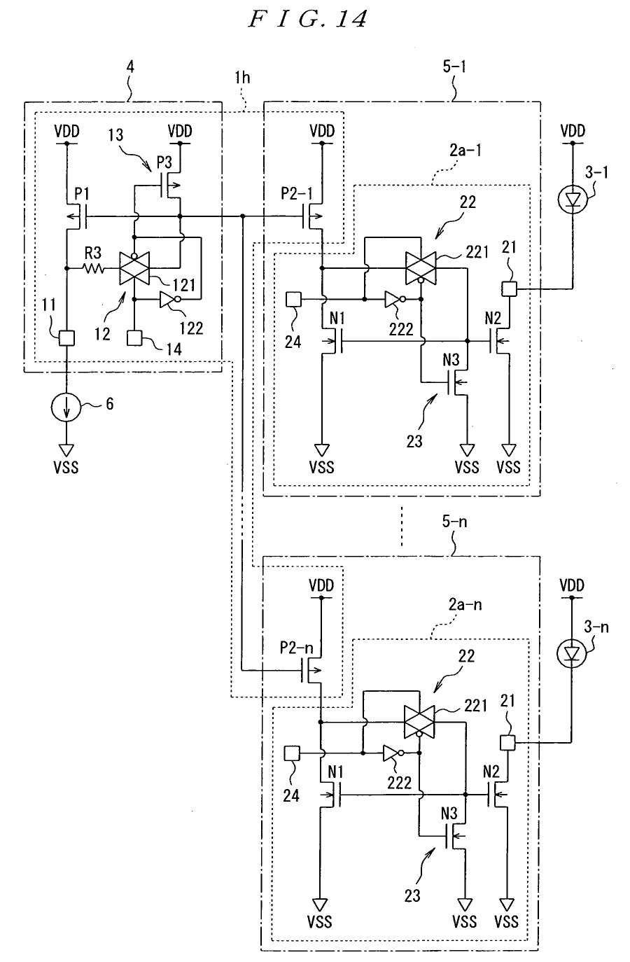

Referring now to FIG. 14, a current load driving circuit according to an eleventh embodiment of the invention includes: a first current mirror circuit 1h; and multiple second current mirror circuits 2a-1 to 2a-n. The second current mirror circuits 2a-1 to 2a-n are configured to drive LEDs 3-1 to 3-n, respectively, which are current loads, and to control turning on and off of the current flowing into the LEDs 3-1 to 3-n, separately or collectively.

That is to say, in the eleventh embodiment, the first current mirror circuit 1f according to the ninth embodiment illustrated in FIG. 12 is changed to the first current mirror circuit 1h, and the second current mirror circuit 2a according to the ninth embodiment is changed to n second current mirror circuits 2a-1 to 2a-n.

Specifically, the first current mirror circuit 1h is devised based on the configuration of the first current mirror circuit 1f illustrated in FIG. 12. The MOS transistor P2 is changed to multiple MOS transistors P2-1 to P2-n. The n second current mirror circuits 2a-1 to 2a-n are devised based on the configuration the second current mirror circuit 2a illustrated in FIG. 12.

In the eleventh embodiment, as illustrated in FIG. 14, the entire circuit is divided into the input circuit 4 and n output circuits 5-1 to 5-n, and the divided position is provided on the voltage route of the first current mirror circuit 1h.

Also, the eleventh embodiment is devised based on the configuration of the ninth embodiment in FIG. 12 except for the configuration that is changed, so the same reference numerals will be given to the same components to omit the descriptions thereof.

According to the above eleventh embodiment, the switching circuit 12 included in the first current mirror circuit 1h enables collective control of each current flowing into the n LEDs 3-1 to 3-n, thereby enabling the collective control of the lightings thereof. On the other hand, the switching circuits 22 included in the n second current mirror circuits 2a-1 to 2a-n allow separate control of each current flowing into the n LEDs 3-1 to 3-n, thereby allowing the separate control of the lightings thereof. Furthermore, according to the eleventh embodiment, the same action and effect as those of the ninth embodiment can be achieved.

Modifications of Embodiments

Modifications of the above embodiments will be described with reference to the drawings.

In the first embodiment illustrated in FIG. 1, the first current mirror circuit 1 is formed of the p-type MOS transistors P1 and P2, and the second current mirror circuit 2 is formed of the n-type MOS transistors N1 and N2.

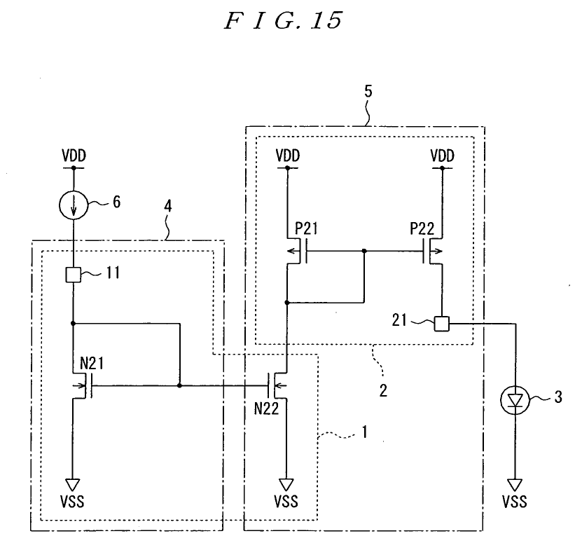

As a variation of the first embodiment, as illustrated in FIG. 15, the p-type MOS transistors P1 and P2 in FIG. 1 may be replaced by n-type MOS transistors N21 and N22, and source electrodes of the n-type MOS transistors N21 and N22 may be connected to the second power supply. In addition, the n-type MOS transistors N1 and N2 in FIG. 1 may be replaced by p-type MOS transistors P21 and P22, and the source electrodes of the p-type MOS transistors P21 and P22 may be connected to the first power supply. In this variation, in the same manner as the first embodiment, the entire circuit is physically divided into the input circuit 4 and the output circuit 5, and the divided position is provided on the voltage route of the first current mirror circuit 1.

Variations of the second to eleventh embodiments can be respectively devised based on the same concept as that of the first embodiment, so the illustrations and descriptions of detailed circuit configurations are omitted.

What is claimed is:

1. A current load driving circuit for driving a current load, comprising:
a first current mirror circuit that outputs a current; and
a second current mirror circuit that receives the current outputted from the first current mirror circuit as an input current and then amplifies the input current to drive the current load,
wherein:
the whole of the first current mirror circuit and the second current mirror circuit is divided into an input circuit and an output circuit; and
the divided position is provided on a voltage route of the first current mirror circuit or a voltage route of the second current mirror circuit.

2. A current load driving circuit for driving a current load, comprising:
a first current mirror circuit that outputs a current; and
a second current mirror circuit that receives the current outputted from the first current mirror circuit as an input current and then amplifies the input current to drive the current load,
wherein:
the whole of the first current mirror circuit and the second current mirror circuit is divided into an input circuit and an output circuit, when the first current mirror circuit and the second current mirror circuit are formed on a semiconductor substrate; and
the divided position is provided on a voltage route of the first current mirror circuit.

3. The current load driving circuit according to claim 1, wherein the first current mirror circuit includes a current source resistor functioning as a current source for supplying a predetermined current to an input side of the first current mirror circuit.

4. The current load driving circuit according to claim 1, wherein the first current mirror circuit includes an electrostatic protection resistor for protecting a transistor in the first current mirror circuit.

5. The current load driving circuit according to claim 3, wherein the current source resistor functions not only as the current source but also to protect a transistor in the first current mirror circuit from static electricity.

6. The current load driving circuit according to claim 1, wherein the first current mirror circuit includes a control circuit for controlling a current of the current load.

7. The current load driving circuit according to claim 1, wherein the second current mirror circuit includes a control circuit for controlling a current of the current load.

8. A current load driving circuit for driving a plurality of current loads, comprising:
a first current mirror circuit that generates a plurality of output currents based on an input current; and
a plurality of second current mirror circuits that receive the plurality of output currents outputted from the first current mirror circuit as input currents, and then amplify the input currents to drive the plurality of current loads,
wherein:
the whole of the first current mirror circuit and the plurality of second current mirror circuits is divided into a single input circuit and a plurality of output circuits; and
the divided position is provided on a voltage route of the first current mirror circuit.

9. A current load driving circuit for driving a plurality of current loads, comprising:
a first current mirror circuit that generates a plurality of output currents based on an input current; and
a plurality of second current mirror circuits that receive the plurality of output currents outputted from the first current mirror circuit as input currents and then amplify the input currents to drive the plurality of current loads,
wherein:
the whole of the current mirror circuits is divided into a single input circuit and a plurality of output circuits, when the first current mirror circuit and the plurality of second current mirror circuits are formed on a semiconductor substrate; and
the divided position is provided on a voltage route of the first current mirror circuit.

10. The current load driving circuit according to claim 8, wherein the first current mirror circuit includes a current source resistor functioning as a current source for supplying a predetermined current to the input side of the first current mirror circuit.

11. The current load driving circuit according to claim 8, wherein the first current mirror circuit includes an electrostatic protection resistor for protecting a transistor in the first current mirror circuit from static electricity.

12. The current load driving circuit according to claim 10, wherein the current source resistor functions not only as the current source but also to protect a transistor in the first current mirror circuit from static electricity.

13. The current load driving circuit according to claim 8, wherein the first current mirror circuit includes a control circuit for collectively controlling currents of the plurality of current loads.

14. The current load driving circuit according to claim 8, wherein each of the plurality of second current mirror circuits includes a control circuit for controlling a current of the current load.
